(19) United States
(12) Patent Application Publication
(10) Pub. No.: US 2009/0032096 A1
(43) Pub. Date: Feb. 5, 2009

(54) PROCESS FOR PRODUCING THIN-FILM DEVICE, AND DEVICES PRODUCED BY THE PROCESS

(75) Inventors: Atsushi TANAKA, Ashigarakami-gun (JP); Kenichi UMEDA, Ashigarakami-gun (JP); Kohei HIGASHI, Ashigarakami-gun (JP); Hiroshi SUNAGAWA, Ashigarakami-gun (JP); Katsuhiro KOHDA, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/182,358

(22) Filed: Jul. 30, 2008

(30) Foreign Application Priority Data
Jul. 30, 2007 (JP) 2007-197001

(51) Int. Cl. H01L 31/00; B32B 27/00; B05D 3/06

(52) U.S. Cl. 136/256; 428/411.1; 427/554; 427/553; 257/E31.001

(57) ABSTRACT

In a process for producing a thin-film device having an inorganic film formed over a resin-based substrate, a thermal-buffer layer is formed over a substrate which contains a resin material as a main component, and a light-cutting layer is formed over the thermal-buffer layer, where the light-cutting layer prevents damage from short-wavelength light to the substrate by reducing the proportion of the short-wavelength light which reaches the substrate. Thereafter, a non-monocrystalline film which is to be annealed is formed over the light-cutting layer, where the non-monocrystalline film transmits the short-wavelength light to such a degree that the short-wavelength light can damage the substrate. Then, an inorganic film is formed by irradiating the non-monocrystalline film with the short-wavelength light so as to anneal the non-monocrystalline film.

### BACKGROUND OF THE INVENTION

1. Field of the Invention

The present invention relates to a process for producing a thin-film device which has an inorganic crystalline film over a low-thermal-resistance substrate such as a resin substrate. The present invention also relates to the thin-film device produced by the above process. The thin-film device can be used in, for example, a semiconductor device such as a thin-film transistor. The present invention further relates to an electro-optic device using the above thin-film device, and a thin-film sensor using the thin-film device.

2. Description of the Related Art

Currently, various flexible devices are receiving attention. The use of the flexible devices is widely spread, and the flexible devices include, for example, electronic paper, flexible displays, and the like.

Basically, the flexible devices have a structure having a thin film of a crystalline semiconductor or metal which is formed in a pattern over a flexible substrate such as a resin substrate. Since the flexible substrate has lower thermal resistivity than the inorganic substrate such as the glass substrate, the entire manufacturing process is required to be executed under the thermal-resistance-limit temperature of the flexible substrate. For example, the thermal-resistance-limit temperature of the resin substrate is normally 150 to 200° C., although the thermal-resistance-limit temperature depends on the material. Even the thermal-resistance-limit temperatures of the thermally resistant materials are approximately 300° C. at the highest.

In particular, the baking temperatures of most inorganic thin films which are to be formed over a substrate as above exceed the thermal-resistance-limit temperature. Therefore, many inorganic thin films cannot be baked by heating. Even in the case where a thin film is baked by laser annealing (which can bake the thin film without directly heating the substrate), it is necessary to take measures to protect the substrate from damage which can be caused by heat transferred from the baked thin film and laser light passing through the thin film and reaching the substrate.

Japanese Unexamined Patent Publication No. 9(1997)-116158 (hereinafter referred to as JP9-116158A) discloses a semiconductor device having a light-weight substrate, a semiconductor thin film, and a heat dissipation means. The heat dissipation means is arranged in a layer between the substrate and the semiconductor thin film, and can sufficiently prevent damage to the substrate which can be caused by heat generated when an energetic beam crystallizes the semiconductor thin film.

Japanese Unexamined Patent Publication No. 11(1999)-102867 (hereinafter referred to as JP11-102867A) discloses a technique for forming a semiconductor thin film by forming an amorphous semiconductor film over a resin substrate through a thermal-buffer layer which stops thermal conduction, and irradiating the amorphous semiconductor film with an energetic beam.

Japanese Unexamined Patent Publication No. 5(1993)-259494 (hereinafter referred to as JP5-259494A) discloses a technique for producing a flexible solar cell. The technique includes a step of crystallization by irradiation with laser light. In the step, in order to suppress damage from heat to a substrate, the substrate is maintained at the temperature of −100° C. to 0° C. during the crystallization.

Japanese Unexamined Patent Publication No. 2004-063924 (hereinafter referred to as JP2004-063924A) discloses a technique for laser annealing a thin film of amorphous silicon over a resin substrate with laser light having a wavelength in the range of 350 to 550 nm. JP2004-063924A reports that since the absorption of the laser light having such a wavelength in the resin substrate is relatively small, the thermal distortion of the substrate caused by the laser light which reaches the substrate can be suppressed when the wavelength of the laser light with which the thin film is irradiated is in the above range.

In the case where a thin film to be crystallized is formed over an entire surface of a substrate, and the material constituting the thin film absorbs almost all of laser light (as an energetic beam) with which the thin film is irradiated, substantially no laser light reaches the substrate. Therefore, in this case, it is possible to prevent heat damage to the substrate by simply preventing heat conduction to the substrate from layers located above the substrate, as disclosed in JP9-116158A, JP11-102867A, and JP5-259494A.

On the other hand, the materials (such as some oxides or some insulating materials) having a great energy bandgap do not exhibit high absorptivity in the visible wavelength range and even in the wavelength range of the excimer laser, which is preferably used in the laser annealing. The wavelength range of the excimer laser includes, for example, the wavelength 308 nm of the XeCl excimer laser and the wavelength 248 nm of the KrF excimer laser. In the case where a film containing such a material as a main component is laser annealed, the laser light with which the film is irradiated for the laser annealing can transmit through the film, reach the substrate, and be absorbed by the substrate, so that the substrate can be damaged. In particular, since the transmittances of the short-wavelength light having the wavelength shorter than 350 nm through many resin substrates are low, it is highly probable that the substrate can be damaged by the heat produced by the absorption of the laser light.

In the technique disclosed in JP2004-063924A, the damage to the substrate is suppressed by performing annealing with the light in the wavelength range of 350 to 550 nm, in which the absorption by the resin substrates is relatively low. However, according to this technique, in order to suppress the damage to the substrate, it is necessary that the film to be annealed exhibit high absorptivity to the light in the above wavelength range as the amorphous silicon. Nevertheless, in the case where the film to be annealed is constituted by a material which has a great energy bandgap as mentioned before, the film does not exhibit high absorptivity to the light in the wavelength range of 350 to 550 nm, so that the technique disclosed in JP2004-063924A cannot be applied to production of a device having such a film.

### SUMMARY OF THE INVENTION

The present invention has been developed in view of the above circumstances.

The first object of the present invention is to provide a process for producing a thin-film device having an inorganic film produced by irradiation with short-wavelength light of a non-monocrystalline film which is formed over a resin substrate and is to be annealed, where the irradiation of the non-monocrystalline film is performed so as to make the inorganic film have satisfactory quality without damaging the resin substrate even in the case where the non-monocrystalline film transmits the short-wavelength light to such a degree that the short-wavelength light can damage the substrate.

Although the high-quality inorganic film produced by the process according to the present invention preferably has satisfactory crystallinity, the high-quality inorganic film produced by the process according to the present invention is not limited to an inorganic crystalline film, and generally includes the inorganic films which can be obtained by annealing a film.

The second object of the present invention is to provide a thin-film device produced by the process achieving the first object.

The third object of the present invention is to provide an electro-optic device using the thin-film device achieving the second object.

The fourth object of the present invention is to provide a thin-film sensor using the thin-film device achieving the second object.

(I) In order to accomplish the first object, the first aspect of the present invention is provided. According to the first aspect of the present invention, there is provided a process for producing a thin-film device. The process comprises the steps of: (A) preparing a substrate which contains a resin material as a main component; (B) forming a thermal-buffer layer over the substrate; (C) forming a light-cutting layer over the thermal-buffer layer, where the light-cutting layer prevents damage from short-wavelength light to the substrate by reducing the proportion of the short-wavelength light which reaches the substrate; (D) forming a non-monocrystalline film over the light-cutting layer, where the non-monocrystalline film transmits the short-wavelength light to such a degree that the short-wavelength light can damage the substrate; and (E) forming an inorganic film by irradiating the non-monocrystalline film with the short-wavelength light so as to anneal the non-monocrystalline film.

In this specification, the “main component” means a component the content of which is 90 weight percent or more, and the “short-wavelength light” means light having a wavelength smaller than 350 nm.

Preferably, the process according to the first aspect of the present invention may also have one or any possible combination of the following additional features (i) to (xi).

(i) The step (D) and the step (E) may be performed one or more times after the step (E) is first performed.

(ii) The process according to the first aspect of the present invention can be preferably applied to production of a thin-film device in which the inorganic film has crystallinity.

(iii) The process according to the first aspect of the present invention can be preferably applied to production of the thin-film device in which the non-monocrystalline film has an energy bandgap of 3.5 eV or greater before the non-monocrystalline film is irradiated with the short-wavelength light.

(iv) The process according to the first aspect of the present invention can be preferably applied to production of a thin-film device in which the non-monocrystalline film contains oxide as a main component.

(v) The process according to the first aspect of the present invention can be preferably applied to production of a thin-film device in which the transmittance of the short-wavelength light through the non-monocrystalline film to be annealed is 10% or higher, and can be more preferably applied to production of a thin-film device in which the transmittance of the short-wavelength light through the non-monocrystalline film is 30% or higher.

(vi) The light-cutting layer may be either a type which absorbs the short-wavelength light or a type which reflects the short-wavelength light.

(vii) The transmittance of the short-wavelength light through the light-cutting layer is required to be so low as to reduce the short-wavelength light to such a degree that the damage from the short-wavelength light to the substrate can be prevented. The transmittance of the short-wavelength light through the light-cutting layer is preferably b 10% or less, and more preferably 5% or less, although the optical transmittance as high as approximately 50% may be allowed in some cases where the short-wavelength light has a specific wavelength and the substrate is formed of a specific material.

(viii) Either of the light-cutting layer and the thermal-buffer layer can be arranged to have a function of a gas barrier.

(ix) The process according to the first aspect of the present invention can preferably include a substep (A-1) of forming a gas-barrier layer on at least one of the bottom surface and the upper surface of the substrate.

(x) In the step (D), it is preferable that the non-monocrystalline film to be annealed be formed by liquid phase deposition.

(xi) The short-wavelength light is preferably pulsed laser light, and more preferably excimer laser light.

(II) In order to accomplish the second object, the second aspect of the present invention is provided. According to the second aspect of the present invention, there is provided a thin-film device. The thin-film device is produced by the process according to the first aspect of the present invention, and comprises the inorganic film formed over the substrate, where the substrate contains the resin material as the main component.

Preferably, the thin-film device according to the second aspect of the present invention may also have one or any possible combination of the following additional features (xii) to (xiv).

(xii) The inorganic film may be a semiconductor film. Preferable examples of the thin-film device having such a semiconductor film are semiconductor devices and solar cells which contain an active layer realized by the semiconductor film.

(xiii) The inorganic film maybe a conductive inorganic film. Preferable example of the thin-film device having such a conductive inorganic film are semiconductor devices and solar cells each of which comprises either a wire or an electrode which is realized by the conductive inorganic film.

(xiv) Other preferable examples of the thin-film device according to the present invention are a semiconductor device and a solar cell each comprising: a wire or an electrode which is realized by a conductive inorganic film; and an active layer realized by a semiconductor film; where each of the conductive inorganic film and the semiconductor film is part of the inorganic film.

(III) In order to accomplish the third object, the third aspect of the present invention is provided. According to the third aspect of the present invention, there is provided an electro-optic device comprising the thin-film device according to the second aspect of the present invention.

In addition, in order to accomplish the fourth object, the fourth aspect of the present invention is provided. According to the fourth aspect of the present invention, there is provided an thin-film sensor comprising the thin-film device according to the second aspect of the present invention.

(IV) The advantages of the present invention are described below.

In the process for producing a thin-film device according to the present invention, before the non-monocrystalline film which is to be annealed is formed over the substrate containing the resin material as the main component, the light-cutting layer is formed over the substrate, and the light-cutting layer prevents damage from the short-wavelength light to the substrate by reducing the proportion of the short-wavelength light which reaches the substrate. Therefore, it is possible to satisfactorily anneal the non-monocrystalline film so as to form the inorganic film having satisfactory quality without damage from the short-wavelength light to the substrate even in the case where the non-monocrystalline film transmits the short-wavelength light to such a degree that the short-wavelength light can damage the substrate.

In addition, when the process according to the present invention is used, it is possible to produce thin-film devices (such as semiconductor devices) which comprise an inorganic film having satisfactory quality and have superior element characteristics.

### BRIEF DESCRIPTION OF THE DRAWINGS

FIG. 1A is a schematic cross-sectional view of the structure of a semiconductor device as a thin-film device according to a first embodiment of the present invention.

FIG. 1B is a schematic cross-sectional view of the structure of an active-matrix substrate containing the semiconductor device of FIG. 1A.

FIGS. 2A, 2B, 2C, 2D, 2E, and 2F are cross-sectional views of the structures in representative steps (A) to (E) in a first part of a process for producing the thin-film device of FIG. 1A.

FIGS. 3A, 3B, 3C, and 3D are cross-sectional views of the structures in representative steps (for forming electrodes) in a second part of the process for producing the thin-film device of FIG. 1A.

FIG. 4 is a graph indicating the wavelength dependence of the optical transmittance of a PET (polyethylene terephthalate) substrate.

FIG. 5 is a graph indicating the wavelength dependence of the optical transmittance of a SiNe film (having the thickness of 89 nm).

FIG. 6 is a graph indicating the wavelength dependence of the optical transmittance of a TiO₂ film (having the thickness of 210 nm).

FIG. 7 is a schematic cross-sectional view of the structure of a solar cell as a thin-film device according to a second embodiment of the present invention.

FIG. 8 is a schematic cross-sectional view of the structure of a thin-film sensor according to a third embodiment of the present invention.

FIG. 9 is an exploded perspective view of the structure of an electro-optic device according to a fourth embodiment of the present invention.

### DESCRIPTION OF PREFERRED EMBODIMENTS

### 1. THIN-FILM DEVICE (FIRST EMBODIMENT)

### 1.1 Structure of Thin-film Transistor and Outline of Process

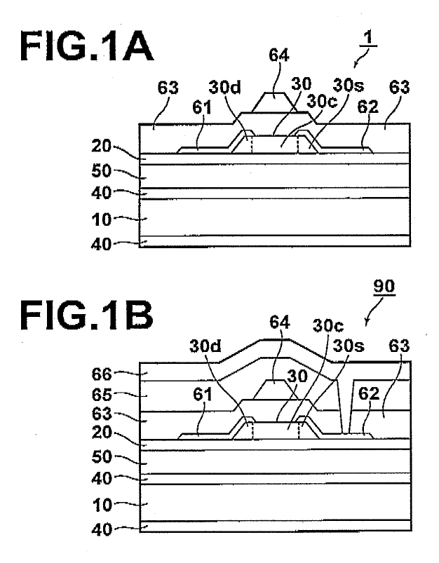

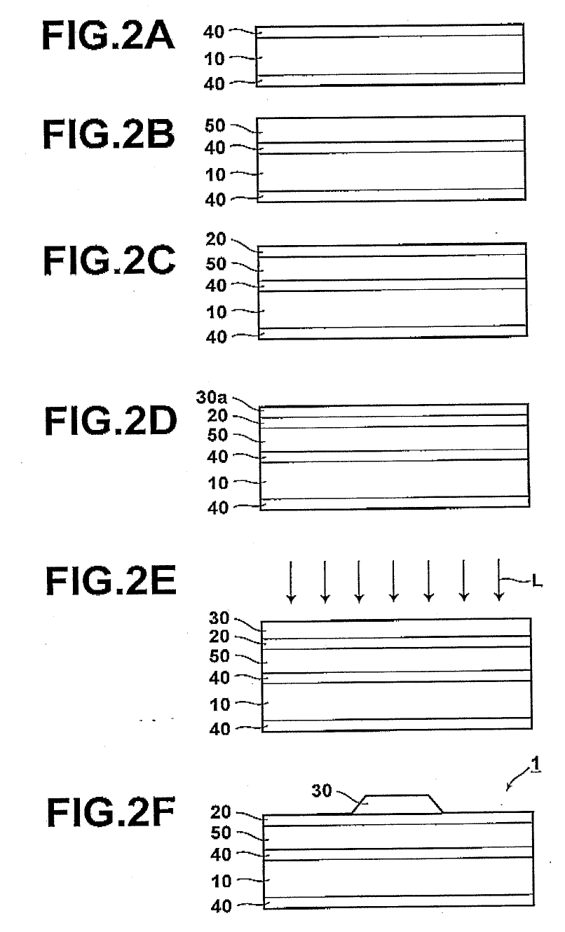

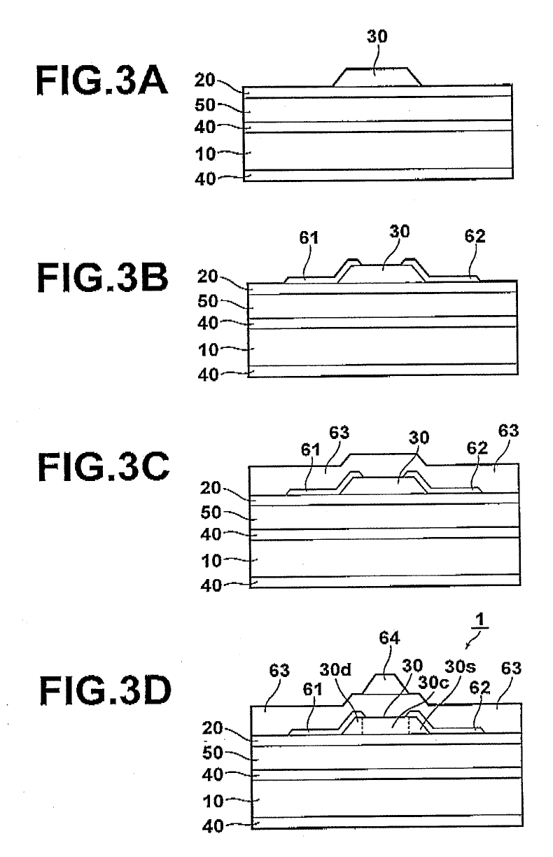

The thin-film device according to the first embodiment, an active-matrix substrate having the thin-film device as a pixel-switch element, and the process for producing the thin-film device and the active-matrix substrate according to the first embodiment are explained below with reference to FIGS. 1A, 1B, 2A, 2B, 2C, 2D, 2E, 2F, 3A, 3B, 3C, and 3D. The thin-film device according to the first embodiment is a semiconductor device (specifically, a thin-film transistor (TFT)). In the following explanations, the thin-film transistor is assumed to be a top-gate type. However, the present invention can also be applied to the bottom-gate type thin-film transistor. FIG. 1A shows a cross section, along the thickness direction, of the semiconductor device 1 as the thin-film device according to the first embodiment, FIG. 1B shows a cross section, along the thickness direction, of the active-matrix substrate containing the semiconductor device of FIG. 1A, FIGS. 2A, 2B, 2C, 2D, 2E, and 2F show cross sections of the structures in representative steps (steps (A) to (E)) in the first part of the process for producing the thin-film device of FIG. 1A, and FIGS. 3A, 3B, 3C, and 3D show cross sections of the structures in representative steps (for forming electrodes) in the second part of the process for producing the thin-film device of FIG. 1A. In FIGS. 1A, 1B, 2A, 2B, 2C, 2D, 2E, 2F, 3A, 3B, 3C, and 3D, the respective elements are illustrated schematically, and the dimensions of the illustrated elements are differentiated from the dimensions of the corresponding elements in the actual system for clarification.

As illustrated in FIG. 1A, the semiconductor device (thin-film device) 1 according to the first embodiment is constituted by a substrate 10, a thermal-buffer layer 50, a light-cutting layer 20, an active layer 30, a gate-insulation film 63, and electrodes 61, 62, and 64. The substrate 10 contains a resin material as a main component, and gas-barrier layers 40 are arranged on the entire bottom surface and the entire upper surface of the substrate 10. The active layer 30 is an inorganic crystalline film of an inorganic material containing one or more metal elements and/or one or more semiconductor elements, although the inorganic crystalline film 30 may contain inevitable impurities. The thermal-buffer layer 50 and the light-cutting layer 20 are formed over the entire upper surface of the substrate 10. The active layer 30 is formed in a pattern over the substrate 10 through the thermal-buffer layer 50 and the light-cutting layer 20.

In the process for producing the semiconductor device 1, the inorganic crystalline film 30 is obtained by forming a non-monocrystalline film 30a to be annealed, over the entire upper surface of the substrate 10, irradiating the non-monocrystalline film 30a with short-wavelength light L so as to anneal and crystallize the non-monocrystalline film 30a (i.e., transform the non-monocrystalline film 30a into an inorganic crystalline film), and patterning the inorganic crystalline film, as illustrated in FIGS. 2D, 2E, and 2F. The manner of the patterning is not specifically limited. For example, the patterning may be performed by photolithography or the like.

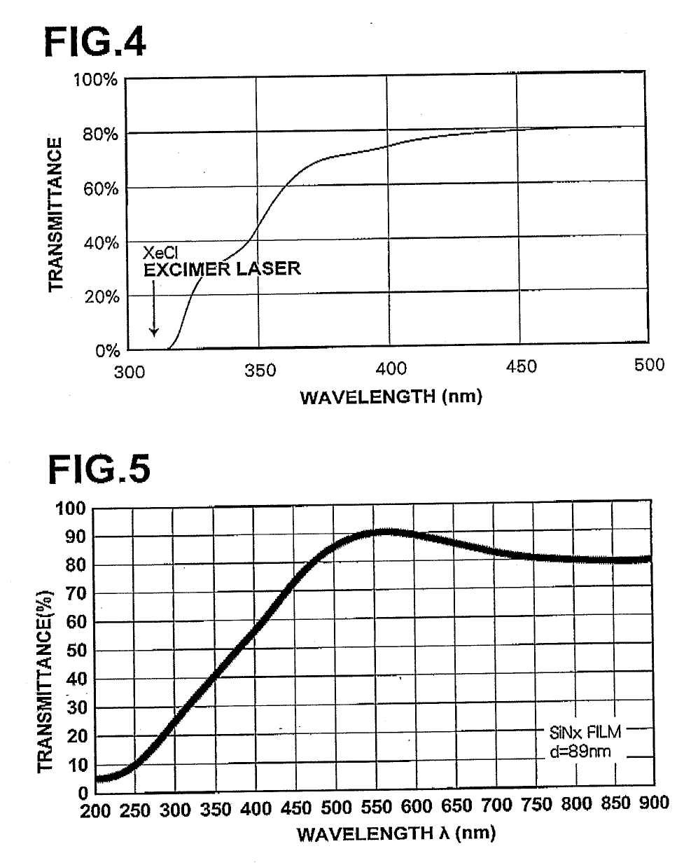

The substrate 10 in the semiconductor device 1 is a resin substrate. Many resin substrates exhibit high absorptivity to the short-wavelength light L. For example, PET (polyethylene terephthalate) absorbs approximately 100% of light at the wavelengths around the oscillation wavelength of the XeCl excimer laser as indicated in FIG. 4, which shows the wavelength dependence of the optical transmittance of a PET (polyethylene terephthalate) substrate. When the short-wavelength light L transmits through the non-monocrystalline film 30a to be annealed, and reaches the substrate 10 (exhibiting high absorptivity as above) during the annealing, the substrate 10 absorbs the short-wavelength light L (having high energy), so that heat is generated and damages the substrate 10.

In the process for producing the semiconductor device 1 according to the first embodiment, the light-cutting layer 20 (reducing the proportion of the short-wavelength light L which reaches the substrate 10) is formed over the substrate 10 before the non-monocrystalline film 30a to be annealed is formed. Therefore, it is possible to prevent the damage to the substrate 10, which can occur if the short-wavelength light L transmits through the non-monocrystalline film 30a and reaches the substrate 10.

If the non-monocrystalline film 30a to be annealed exhibits high absorptivity to the short-wavelength light L as the amorphous silicon film, the short-wavelength light L is absorbed by the non-monocrystalline film 30a with high efficiency, and only a small part of the short-wavelength light L transmits through the non-monocrystalline film 30a, so that there is almost no risk that such a small part of the short-wavelength light L damages the substrate 10.

Therefore, the process for producing the semiconductor device 1 according to the first embodiment can be preferably used in the case where the non-monocrystalline film 30a to be annealed does not exhibit sufficient absorptivity to the short-wavelength light L. Although the non-monocrystalline film 30a (to be annealed) to which the process according to the first embodiment can be preferably applied depends on the wavelength of the short-wavelength light L as well as the absorptivity of the substrate 10 to the short-wavelength light L, the process according to the first embodiment can be preferably applied to production of a thin-film device in which the transmittance of the short-wavelength light L through the non-monocrystalline film 30a is 10% or higher, and can be more preferably applied to production of a thin-film device in which the transmittance of the short-wavelength light L through the non-monocrystalline film 30a is 30% or higher. In the case where the transmittance of the short-wavelength light L through the non-monocrystalline film 30a is 30% or higher, if the substrate 10 is not arranged as above, it is highly probable that the substrate 10 can be damaged from the short-wavelength light L during the annealing.

In the process for producing the semiconductor device 1 according to the first embodiment, the constituent material of the non-monocrystalline film 30a is not specifically limited as long as the non-monocrystalline film 30a exhibits the transmittance as above, and can be crystallized by irradiation with the short-wavelength light L. In many cases, the non-monocrystalline film 30a which is formed of a material having an energy bandgap of 3.5 eV or greater (as the semiconductor materials containing oxide as a main component) and has a thickness within the normal range of the thicknesses of the non-monocrystalline films in many thin-film devices exhibits a 10% or higher transmittance of the short-wavelength light L, i.e., exhibits low absorptivity to the short-wavelength light L. Therefore, the process for producing the semiconductor device 1 according to the first embodiment is particularly effective in the case where the semiconductor device 1 in which the non-monocrystalline film 30a to be annealed exhibits low absorptivity as above.

### 1.2 Details of Process

Hereinbelow, the process for producing the thin-film device (semiconductor device) 1 is explained in detail below with reference to FIGS. 2A, 2B, 2C, 2D, 2E, 2F, 3A, 3B, 3C, and 3D.

### 1.2.1 Process Up To Annealing

First, the first part of the process according to the first embodiment including the steps (A) to (E) is explained in detail below. In the first part of the process, the gas-barrier layers 40, the thermal-buffer layer 50, and the light-cutting layer 20, and the non-monocrystalline film 30a to be annealed are formed in the steps (A) to (D) respectively illustrated in FIGS. 2A, 2B, 2C, and 2D, and then the inorganic crystalline film 30 is formed by annealing and patterning in the step (E) as illustrated in FIGS. 2E and 2F.

In the step (A), the substrate 10 is prepared as illustrated in FIG. 2A, where the gas-barrier layers 40 are arranged on the bottom and upper surfaces of the substrate 10. Specifically, the step (A) includes a substep (A-1) of forming the gas-barrier layers 40 on the bottom and upper surfaces of the substrate 10. The material of the substrate 10 is not specifically limited as long as the substrate 10 is a flexible substrate containing a resin material as a main component. For example, the substrate 10 may be formed of a resin of polyethylene terephthalate (PET), polyethylene naphthalate (PEN), polyimide (PI), or the like. It is preferable that the substrate 10 have superior thermal resistivity.

The gas-barrier layers 40 is provided for suppressing adverse influences, on the characteristics of the thin-film device 1, of oxygen, water, and the like which exist in the atmosphere and invade into the thin-film device 1 through the substrate 10 (which is permeable to gas). Generally, the gas-barrier layers 40 are required to have a water-vapor permeability coefficient of approximately 1 ×10⁻³, to 1×10⁻² g/m²/day, although the permeability coefficient of the gas-barrier layers 40 depends on the material properties and thickness of the gas-barrier layers 40. Each of the gas-barrier layers 40 may be constituted by a plurality of sublayers.

In the case where the gas-barrier layers are required to be thick, and tend to be colored by irradiation with short-wavelength light L, the characteristics of the thin-film device 1 can be adversely affected by irradiation with short-wavelength light L. Therefore, conventionally, it has been considered preferable that the gas-barrier layers be as resistant to absorption of the short-wavelength light L as possible. The SiNₓ films, the SiO₂ films, and the like are examples of the gas-barrier layers 40 resistant to absorption of the short-wavelength light L. The properties of the SiNe films vary with the composition (i.e., the value of x), and the composition varies with the film-formation condition. Thus, conventionally, it has also been considered preferable that the gas-barrier layers have such a composition as to maximize the resistance to absorption of the short-wavelength light L, and be formed under such a film-formation condition as to realize satisfactory gas-barrier characteristics.

The above gas-barrier layers can also be used as the gas-barrier layers 40 in the thin-film device (semiconductor device) 1 according to the first embodiment. However, in the thin-film device 1, the light-cutting layer 20 is formed above the gas-barrier layers 40 (in the step (C) as explained later), and reduces the proportion of the short-wavelength light L which reaches the gas-barrier layers 40. Since the proportion of the short-wavelength light L which reaches the gas-barrier layers 40 is reduced by the light-cutting layer 20, no requirement is imposed on the absorption characteristics of the short-wavelength light L in the gas-barrier layers 40 as long as the gas-barrier layers 40 have a sufficient gas-barrier function.

The manner of formation of the gas-barrier layers 40 is not specifically limited. For example, the gas-barrier layers 40 may be formed by sputtering, PVD (physical vapor deposition), evaporation, or the like.

Next, in the step (B), the thermal-buffer layer 50 is formed over the substrate 10 having the gas-barrier layers 40 as illustrated in FIG. 2B. The thermal-buffer layer 50 is provided for preventing damage to the light-cutting layer 20 from the heat transferred from the light-cutting layer 20 (as explained later). Therefore, it is necessary that the thermal conductivity of the thermal-buffer layer 50 be low. The thermal-buffer layer 50 is, for example, a SiO₂ film. The thermal conductivity which the thermal-buffer layer 50 is required to have depends on the energy of the short-wavelength light L. The thermal conductivity of bulk SiO₂ is 2.8×10⁻³ cal/cm/sec/K. For example, JP11-102867A, paragraph No. 0040 reports that in the case where the short-wavelength light L is excimer laser light, the effect of thermally buffering the resin substrate sufficiently works when the thickness of the SiO₂ film is 1.0 to 2.0 micrometers. Therefore, in the case where the short-wavelength light L is excimer laser light, it is preferable that the gas-barrier layers 40 have a thermal conductivity equivalent to the thermal conductivity of the SiO₂ film having a thickness of 1.0 to 2.0 micrometers.

The manner of formation of the thermal-buffer layer 50 is not specifically limited. For example, the thermal-buffer layer 50 may be formed in a similar manner to the gas-barrier layers 40.

In the case where the thermal-buffer layer 50 also has a gas-barrier function, the thermal-buffer layer 50 may take on the function of a gas-barrier layer, or part of sublayers constituting a gas-barrier layer.

Subsequently, in the step (C), the light-cutting layer 20 is formed over the thermal-buffer layer 50 as illustrated in FIG. 2C. The light-cutting layer 20 is provided for reducing the proportion of the short-wavelength light L which reaches the substrate 10 so that the substrate 10 is not damaged by heat which is generated in the substrate 10 when the short-wavelength light L is absorbed in the substrate 10. The substrate 10 is damaged or not damaged according to the wavelength of the short-wavelength light L and the absorption characteristics of the short-wavelength light L.

As the PET substrate indicated in FIG. 4, the substrate 10 may be damaged even when the absorptance of the substrate 10 is approximately 15% in some cases where the energy of the short-wavelength light L is very high, and may not be damaged even when the absorptance of the substrate 10 is approximately 30% in other cases where the energy of the short-wavelength light L is relatively low. In consideration of the absorptances of the short-wavelength light L in major materials of which the resin-based substrate can be formed, the transmittance of the short-wavelength light L in the light-cutting layer 20 is preferably 10% or lower, and more preferably 5% or lower.

The manner of formation of the light-cutting layer 20 is not specifically limited. For example, the light-cutting layer 20 may be formed in a similar manner to the gas-barrier layers 40.

The material of the light-cutting layer 20 is not specifically limited as long as the light-cutting layer 20 can reduce the proportion of the short-wavelength light L (having the wavelength shorter than 350 nm) which reaches the substrate 10. The light-cutting layer 20 may be either a type which absorbs the short-wavelength light or a type which reflects the short-wavelength light.

In the case where the light-cutting layer 20 is the type which absorbs the short-wavelength light L, the light-cutting layer 20 may be formed of, for example, SiNₓ, SiO, SiNO, TiO₂, ZnS, or the like. As explained before for the gas-barrier layers 40, the properties of SiNe vary with the film-formation condition. It is preferable that the light-cutting layer 20 be formed so as to have a composition which realizes a property of sufficiently absorbing the short-wavelength light L.

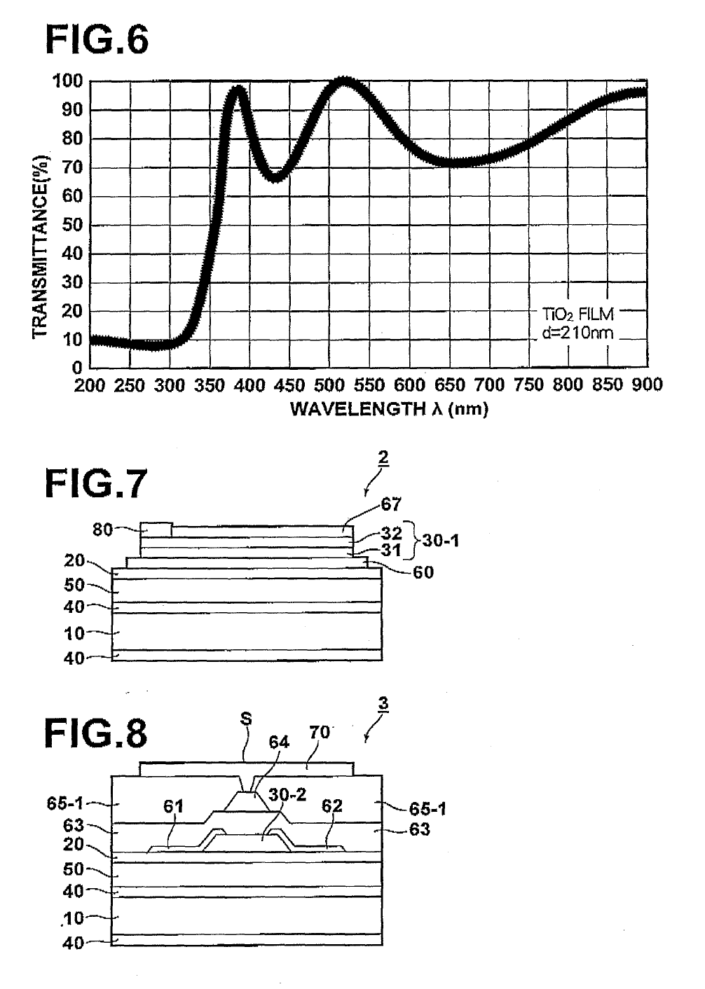

The thickness of the light-cutting layer 20 is determined according to the optical transmittance and the material properties of the light-cutting layer 20, where the optical transmittance of the light-cutting layer 20 is determined based on the absorption characteristics of the short-wavelength light L in the light-cutting layer 20. FIGS. 5 and 6 respectively show the wavelength dependences of the optical transmittances of a SiNₓ film and a TiO₂ film as the light-cutting layer 20.

Specifically, the SiNₓ film in FIG. 5 is formed by RF sputtering in the atmosphere of a mixture of Ar and 5.0 volume percent N₂ under the condition that the output power is 300 W and the vacuum degree is 0.67 Pa. The thickness of the SiNe film is 89 nm. The wavelength dependence of the optical transmittance of the SiNₓ film in FIG. 5 indicates that the transmittance of the short-wavelength light having a wavelength smaller than 350 nm through the SiNe film having the thickness of 89 nm (or greater) is approximately 40% or smaller.

In addition, the TiO₂ film in FIG. 6 is formed by RF sputtering in the atmosphere of a mixture of Ar and 1.0 volume percent O₂ under the condition that the output power is 400 W and the vacuum degree is 0.67 Pa. The thickness of the TiO₂ film is 210 nm. The wavelength dependence of the optical transmittance of the TiO₂ film in FIG. 6 indicates that the transmittance of the short-wavelength light having a wavelength smaller than 350 nm through the TiO₂ film having the thickness of 210 nm (or greater) is approximately 30% or smaller, and the transmittance of the short-wavelength light having a wavelength of 320 nm or smaller through the TiO₂ film having the thickness of 210 nm (or greater) is approximately 10% or smaller.

Therefore, it is possible to determine the material and the thickness of the light-cutting layer 20 according to a required transmittance of the light-cutting layer 20.

In the case where the light-cutting layer 20 has a gas-barrier function, the light-cutting layer 20 may take on the function of a gas-barrier layer, or part of sublayers constituting a gas-barrier layer.

In the case where the light-cutting layer 20 is the type which reflects the short-wavelength light L, no specific limitation is imposed on the light-cutting layer 20 as long as the reflectance of the light-cutting layer 20 against the short-wavelength light L is sufficient. For example, the light-cutting layer 20 may be a metal film exhibiting a sufficient reflectance corresponding to a required transmittance.

After the light-cutting layer 20 is formed as above, the non-monocrystalline film 30a to be annealed is formed over the entire upper surface of the substrate 10 covered with the gas-barrier layers 40, the thermal-buffer layer 50, and the light-cutting layer 20 as illustrated in FIG. 2D in the step (D), and is then annealed by irradiating the non-monocrystalline film 30a with the short-wavelength light as illustrated in FIG. 2E in the step (E), so that the inorganic crystalline film 30 is formed.

The inorganic crystalline film 30 as the active layer is, for example, a metal-oxide film or a semiconductor film. An example of the inorganic crystalline film 30 is a metal-oxide film containing one or more of the metal elements In, Ga, Zn, Sn, and Ti and having a semiconductive property.

The manner of formation of the non-monocrystalline film 30a to be annealed in the semiconductor device 1 is not specifically limited. In the case where the non-monocrystalline film 30a is formed by vapor phase deposition such as sputtering, the non-monocrystalline film 30a has crystallinity even before the non-monocrystalline film 30a is annealed with the short-wavelength light L. However, in order to produce a semiconductor device 1 having satisfactory element characteristics, it is preferable that the inorganic crystalline film 30 have high crystallinity. Therefore, it is preferable that the inorganic crystalline film 30 be produced by annealing the non-monocrystalline film 30a with the short-wavelength light L so as to improve the crystallinity.

On the other hand, in the case where the non-monocrystalline film 30a is formed by liquid phase deposition, the inorganic crystalline film 30 can be produced by preparing a raw-material solution containing an organic solvent and one or more inorganic elements constituting the inorganic crystalline film 30, forming the non-monocrystalline film 30a by application of the raw-material solution, and crystallizing the non-monocrystalline film 30a by annealing with the short-wavelength light L. In contrast to the vapor phase deposition, the non-monocrystalline film 30a formed by simply applying the raw-material solution for the liquid phase deposition is not a semiconductor film having functionality. Therefore, the step of annealing the non-monocrystalline film 30a with the short-wavelength light L is essential for obtaining the inorganic crystalline film 30. For example, the inorganic crystalline film 30 can be formed by the liquid phase deposition as follows.

That is, in the step (D), a raw-material solution of an organic solvent and a raw material which contains one or more metal elements constituting the inorganic crystalline film 30 is prepared, and the non-monocrystalline film 30a to be annealed is formed over the light-cutting layer 20 (formed over the substrate 10) by liquid phase deposition, i.e., by applying the raw-material solution to the light-cutting layer 20 as illustrated in FIG. 2D.

It is preferable to remove most of the organic solvent from the non-monocrystalline film 30a by room-temperature drying or the like, although the non-monocrystalline film 30a may be slightly heated to such a degree that the crystallization does not occur (e.g., to the temperature of approximately 50° C. to 200° C.).

An example of the raw-material solution is a raw-material solution containing an organic solvent and an organic precursor material which contains an inorganic material as a constituent of the inorganic crystalline film 30. An example of the organic precursor material is a metal alkoxide compound or the like (which can be used as a raw material in a sol-gel process). Alternatively, a raw-material solution containing an organic solvent and one or both of an inorganic material and an inorganic-organic complex precursor material may be used. An example of such a raw-material solution is a dispersion solution of inorganic particles and/or inorganic-organic complex particles, which is obtained by heating and stirring a liquid containing an organic solvent and an organic precursor material so as to produce particles of the organic precursor material in the liquid. (Such a technique of producing a dispersion solution of nanoparticles is hereinafter referred to as the nanoparticle method.) In the case where the nanoparticle method is used for producing the raw-material solution for the non-monocrystalline film 30a to be annealed, the amount of organic materials contained in the non-monocrystalline film 30a is reduced by the production of the particles before the film formation. In addition, the nanoparticles behave as crystal nuclei in crystal growth in the subsequent crystallization step, so that the crystal growth is facilitated. Therefore, it is preferable to use the nanoparticle method. In the case where the nanoparticle method is used, part of the organic precursor material may not be transformed into particles and may remain in the non-monocrystalline film 30a.

The manner of application of the raw-material solution is not specifically limited, and the raw-material solution may be applied, for example, by coating or printing. The coating may be spin coating, dip coating, or the like, and the printing may be inkjet printing, screen printing, or the like. In particular, the printing techniques such as the inkjet printing and the screen printing enable direct imaging of a desirable pattern.

In the step (E), the non-monocrystalline film 30a to be annealed is crystallized so as to form the inorganic crystalline film 30 as illustrated in FIG. 2E. The crystallization is realized by laser annealing, which is performed by irradiating the non-monocrystalline film 30a with the short-wavelength light L. Since the laser annealing is a scanning type heating processing in which thermal rays (light) having high energy are used, the crystallization efficiency is high, and it is possible to control the energy which reaches the substrate, by changing the laser-irradiation condition including the scanning speed, the laser power, and the like. That is, in the laser annealing, the substrate is not directly heated, and the laser-irradiation condition can be adjusted according to the thermal resistivity of the substrate. Therefore, use of the laser annealing is preferable in the case where the low-thermal-resistance substrate such as the resin substrate is used.

Although the laser-light source used in the laser annealing is not specifically limited, a preferable example is the pulsed laser such as the excimer laser. The short-wavelength pulsed-laser light such as the excimer laser light is preferable, since great part of the energy of the short-wavelength pulsed-laser light is absorbed in a near-surface region, and it is easy to control the energy which reaches the substrate.

For example, in the case where the inorganic crystalline film 30 is a film of InGaZnO₄, it is possible to realize an InGaZnO₄ film having satisfactory crystallinity, by laser annealing the non-monocrystalline film 30a with excimer laser at the wavelength of 248 nm so as to realize the irradiation power of 1 to 300 mJ/cm².

After the crystallization by annealing, the inorganic crystalline film 30 is patterned by photolithography. Thus, the formation of the inorganic crystalline film 30 is completed as illustrated in FIG. 2F. The manner of the photolithography is not specifically limited. For example, the photolithography technique in which the contact exposure and the dry etching are combined may be used.

### 1.2.2 Formation of Electrodes

Next, the second part of the process according to the first embodiment performed for forming the electrodes in the semiconductor device 1 on the structure of FIG. 2F (FIG. 3A) is explained in detail below with reference to FIGS. 3A, 3B, 3C, and 3D.

In the second part of the process, the drain electrode 61 and the source electrode 62 are formed on the inorganic crystalline film 30 as illustrated in FIG. 3B, and thereafter the gate-insulation film 63 of SiO₂ or the like is formed over the structure of the FIG. 3B, as illustrated in FIG. 3C. Further, the gate electrode 64 of n⁺Si, Al, an Al alloy, Ti, or the like is formed on the gate-insulation film 63 as illustrated in FIG. 3D.

The manners of the formation of the drain electrode 61, the source electrode 62, and the gate electrode 64 are not specifically limited. However, in the case where these electrodes are formed of a translucent electrode material such as SnO₂, ZnO:Al (aluminum-doped zinc oxide), or ITO (indium tin oxide), it is preferable to form each of the drain electrode 61, the source electrode 62, and the gate electrode 64 by forming in a pattern a film which contains the constituent elements of each of the drain electrode 61, the source electrode 62, and the gate electrode 64 and is to be annealed, and thereafter annealing the film, in a similar manner to the formation of the inorganic crystalline film 30. In addition, various wires on the semiconductor device 1 can also be formed in similar manners to the above electrodes. That is, each of the electrodes and the wires can be produced by preparing a raw-material solution for the electrode or wire, and performing the operations similar to the aforementioned steps (D) and (E). Alternatively, the electrodes and the wires may be produced by patterning using lithography or the like after film formation by CVD (chemical vapor deposition), sputtering, or the like.

Although the thickness of the gate-insulation film 63 is not specifically limited, a preferable example of the thickness is approximately 100 nm. In addition, one of the techniques mentioned before for the formation of the gas-barrier layers 40 can also be used in formation of the gate-insulation film 63.

After the formation of the gate electrode 64, processing for lowering the resistance in a source region 30s and a drain region 30d in the inorganic crystalline film 30 is performed by using the gate electrode 64 as a mask. Thus, the inorganic crystalline film 30 becomes the active layer as illustrated in FIG. 3D, and the production of the thin-film transistor (TFT) 1 is completed. At this time the region between the source region 30s and the drain region 30d in the inorganic crystalline film 30 becomes a channel region 30c.

### 1.2.3 Formation of Active-matrix Substrate

The active-matrix substrate 90 according to the present embodiment can be produced by forming an array of structures in each of which the active layer 30, the electrodes 61, 62, and 64 are formed as illustrated in FIG. 1A, on the layers of the substrate 10, the gas-barrier layers 40, the thermal-buffer layer 50, and the light-cutting layer 20, and then forming an interlayer insulation film 65 (of SiO₂, SiN, or the like) and pixel electrodes 66 over the array of the above structures as illustrated in FIG. 1B. Each of the pixel electrodes 66 is electrically connected to the source electrode 62 in one of the above structures through a contact hole formed by etching (e.g., dry etching, wet etching, or the like).

During the production of the active-matrix substrate 90, wires of scanning lines and signal lines are formed. The gate electrodes 64 have the function of the scanning lines in some cases, or the scanning lines are arranged separately from the gate electrode 64 in other cases. In addition, the drain electrodes 61 have the function of the signal lines in some cases, or the signal lines are arranged separately from the drain electrodes 61 in other cases.

### 1.3 Advantages of First Embodiment

The advantages of the process for producing a thin-film device (semiconductor device) 1 according to the first embodiment are summarized below.

(1) Although the main component of the substrate 10 is resin, the light-cutting layer 20 (reducing the proportion of the short-wavelength light L which reaches the substrate 10 and preventing damage from the short-wavelength light L to the substrate 10) is formed over the substrate 10 before the non-monocrystalline film 30a to be annealed is formed over the substrate 10, Therefore, it is possible to prevent damage to the substrate 10 from the short-wavelength light L which passes through the non-monocrystalline film 30a and reaches the substrate 10. Thus, even in the case where the non-monocrystalline film transmits the short-wavelength light to such a degree that the short-wavelength light can damage the substrate, it is possible to crystallize the non-monocrystalline film 30a without damaging the substrate 10, and produce the inorganic crystalline film 30 having satisfactory crystallinity.

(2) Since the inorganic crystalline film 30 having satisfactory crystallinity is the active layer of the semiconductor device 1 according to the first embodiment, the semiconductor device 1 has superior element characteristics. Since the active-matrix substrate 90 uses the semiconductor device 1 having the superior element characteristics, the active-matrix substrate 90 exhibits high performance.

### 2. THIN-FILM DEVICE (SECOND EMBODIMENT)

The thin-film device according to the second embodiment and the process for producing the thin-film device according to the second embodiment are explained below with reference to FIG. 7. The thin-film device according to the second embodiment is a solar cell. FIG. 7 shows a cross section, along the thickness direction, of the solar cell 2 as the thin-film device according to the second embodiment. In FIG. 7, the respective elements are illustrated schematically, and the dimensions of the illustrated elements are differentiated from the dimensions of the corresponding elements in the actual system for clarification.

As illustrated in FIG. 7, the solar cell (thin-film device) 2 according to the second embodiment is constituted by a substrate 10, a thermal-buffer layer 50, a light-cutting layer 20, an active layer 30-1, a lower electrode 60, an upper electrode 80, and an antireflection layer 67. The substrate 10 contains a resin material as a main component, and the gas-barrier layers 40 are arranged on the bottom surface and the upper surface of the substrate 10. The active layer 30-1 is an inorganic crystalline film of an inorganic material containing one or more metal elements and/or one or more semiconductor elements, although the inorganic crystalline film 30-1 may contain inevitable impurities. The active layer 30-1 is formed in a pattern over the substrate 10 through the thermal-buffer layer 50 and the light-cutting layer 20.

The inorganic crystalline film 30-1 as the active layer is a lamination of a plurality of sublayers each having different semiconductivity. In the following explanations, it is assumed that the inorganic crystalline film 30-1 has a two-layer structure in which a p-type semiconductor film 31 and an n-type semiconductor film 32 are laminated. In addition, the antireflection layer 67 is formed on an area of the upper surface of the n-type semiconductor film 32 on which the upper electrode 80 is not formed.

Hereinbelow, the process for producing the solar cell 2 according to the second embodiment is explained with reference to FIG. 7.

First, the thermal-buffer layer 50 and the light-cutting layer 20 are formed over the substrate 10 (containing a resin material as a main component, and having the gas-barrier layers 40 on the bottom surface and the upper surface) in similar manners to the steps (A) to (C) in the first embodiment illustrated in FIGS. 2A to 2C. Then, the lower electrode 60 of a translucent electrode material such as SnO₂, ZnO:Al (aluminum-doped zinc oxide), or ITO (indium tin oxide) is formed on the light-cutting layer 20 by forming on the entire upper surface of the light-cutting layer 20 a non-monocrystalline film which contains one or more metal elements constituting the lower electrode 60 and is to be annealed, and annealing the non-monocrystalline film with the short-wavelength light L, in a similar manner to the first embodiment. In addition, various wires on the solar cell 2 can also be formed in similar manners. Alternatively, the electrodes, the wires, and the like may be produced by patterning using lithography or the like after film formation by CVD, sputtering, or the like.

Next, the inorganic crystalline film 30-1 (as the active layer) is formed in a similar manner to the inorganic crystalline film 30 in the first embodiment. In the solar cell 2, the inorganic crystalline film 30-1 is constituted by the semiconductor films. For example, the p-type semiconductor film 31 may be formed of copper aluminum oxide, and the n-type semiconductor film 32 may be formed of ZnO or the like. It is preferable that the p-type semiconductor film 31 and the n-type semiconductor film 32 be formed of materials which can achieve the highest possible efficiency in absorption of sunlight. Raw-material solutions similar to the aforementioned examples preferable for the first embodiment can also be used in for the inorganic crystalline film 30-1 in the second embodiment.

Thereafter, the upper electrode 80 is formed in a pattern on an area of the upper surface of the n-type semiconductor film 32 as illustrated in FIG. 7. The manner of formation of the upper electrode 80 is similar to the lower electrode 60. Further, the antireflection layer 67 is formed on the other area of the upper surface of the n-type semiconductor film 32 on which the upper electrode 80 is not formed. For example, the antireflection layer 67 is formed of MgF₂ or the like.

In addition, various wires on the solar cell 2 can also be formed in similar manners to the wiring in the lower electrode 60 and the upper electrode 80. Alternatively, the electrodes, the wires, and the like may be produced by patterning using lithography or the like after film formation by CVD (chemical vapor deposition), sputtering, or the like.

Thus, production of the solar cell 2 is completed. In the case where the electrodes and the active layer are formed of translucent materials, the solar cell 2 can be a transparent solar cell. The transparent solar cells can generate electric power by absorbing ultraviolet light (which can adversely affect human health), the transparent solar cells are expected to be used in window glasses and the like.

Since the steps in the process for producing the solar cell (thin-film device) 2 according to the second embodiment up to the crystallizaton of the non-monocrystalline film are similar to the corresponding steps in the process according to the first embodiment, the process according to the second embodiment and the solar cell 2 produced by the process according to the second embodiment have similar advantages to the process according to the first embodiment and the thin-film device 1 produced by the process according to the first embodiment. According to the second embodiment, it is possible to easily produce a thin-film device (solar cell) 2 having high crystallinity and superior element characteristics, at low cost.

Although, in the second embodiment, the semiconductor film as the active layer is formed by forming the non-monocrystalline film to be annealed, and annealing the non-monocrystalline film by irradiation with the short-wavelength light L, alternatively, it is possible to form the semiconductor film in another manner. For example, in order to produce a solar cell which can efficiently absorb visible light, instead of the transparent solar cell, Si, CIGS (Cu(In₁-x,Gax) Se₂, and copper-indium-gallium-selenium-based materials can be preferably used as the material of the semiconductor film as the active layer. Further, alternatively, the above semiconductor film may also be produced by patterning using lithography or the like after film formation by CVD (chemical vapor deposition), sputtering, or the like.

### 3. THIN-FILM SENSOR (THIRD EMBODIMENT)

The thin-film sensor according to the third embodiment is explained below with reference to FIG. 8, which shows a cross section, along the thickness direction, of the thin-film sensor 3 according to the third embodiment of the present invention.

As illustrated in FIG. 8, the thin-film sensor 3 according to the third embodiment is constituted by the top-gate type semiconductor device 1 (of FIG. 1A) according to the first embodiment, an interlayer insulation film 65-1 (of SiO₂, SiN, or the like) formed on the semiconductor device 1, and a sensing element 70 arranged over the interlayer insulation film 65-1 and connected to the gate electrode 64 through a contact hole formed through the interlayer insulation film 65-1. The sensing element 70 is a metal layer, and has an exposed surface as a sensing surface S. It is preferable that the sensing surface S be surface modified so that the sensing surface S can be combined with a material R to be sensed. The surface modification is chosen according to the use of the thin-film sensor 3. For example, the surface modification is a receptor such as an antibody in the case where the thin-film sensor 3 is used as a protein sensor,or a probe DNA in the case where the thin-film sensor 3 is used as a DNA chip. The interlayer insulation film 65-land the contact hole in the thin-film sensor 3 according to the third embodiment can be formed in similar manners to the interlayer insulation film 65 and the contact hole in the active-matrix substrate 90 according to the first embodiment.

When the material R to be sensed is combined with the sensing surface S, the potential profile at the sensing surface S changes, so that a potential difference occurs between before and after the combining. Therefore, the material R to be sensed can be sensed by detecting the potential difference by use of the semiconductor device 1.

Since the thin-film sensor 3 according to the third embodiment is constructed by using the semiconductor device 1 according to the first embodiment, and the semiconductor device 1 is superior in the element characteristics, the thin-film sensor 3 is also superior in the element characteristics and has satisfactory sensitivity.

### 4. ELECTRO-OPTIC DEVICE (FOURTH EMBODIMENT)

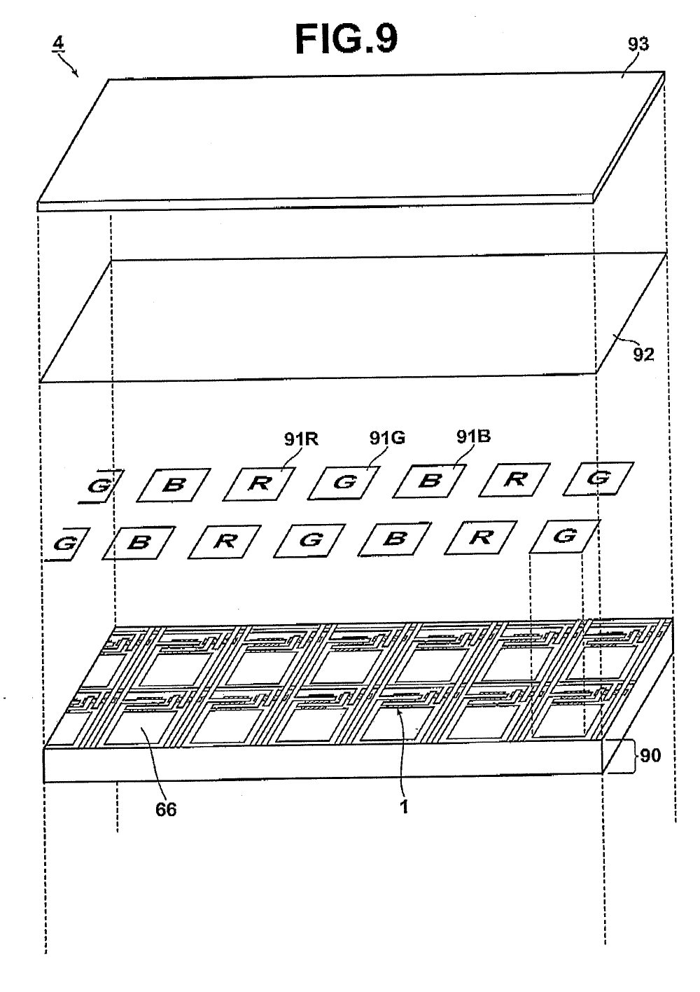

Hereinbelow, the structure of an electro-optic device according to the fourth embodiment of the present invention is explained. The present invention can be applied to organic electroluminescence (EL) devices, liquid crystal devices, and the like. In the fourth embodiment, the present invention is applied to an organic EL device as an example of the electro-optic device according to the present invention. FIG. 9 is an exploded perspective view of the organic EL device according to the fourth embodiment.

As illustrated in FIG. 9, the organic EL device 4 according to the present embodiment is produced by forming light-emission layers 91R, 91G, and 91B in predetermined patterns on the active-matrix substrate 90 according to the first embodiment, and thereafter forming a common electrode 92 and a sealing film 93 in this order over the light-emission layers 91R, 91G, and 91B. The light-emission layers 91R, 91G, and 91B respectively emit red light (R), green light (G), and blue light (B) when electric current is applied to the light-emission layers 91R, 91G, and 91B.

Alternatively, the organic EL device 4 may be sealed by using another type of sealing member such as a metal can or a glass substrate, instead of the use of the sealing film 93. In this case, a drying agent such as calcium oxide may be contained in the sealed structure of the organic EL device 4.

The predetermined patterns in which the light-emission layers 91R, 91G, and 91B are formed correspond to pixel electrodes 66 so that each pixel is constituted by three dots respectively emitting red light, green light, and blue light. The common electrode 92 and the sealing film 93 are formed over the substantially entire upper surface of the active-matrix substrate 90.

In the organic EL device 4, the polarity of the pixel electrodes 66 is opposite to the polarity of the common electrode 92. That is, the pixel electrodes 66 are cathodes when the common electrode 92 is an anode, and the pixel electrodes 66 are anodes when the common electrode 92 is a cathode. The light-emission layers 91R, 91G, and 91B emit light when positive holes injected from an anode and electrons injected from a cathode recombine and the recombination energy is released.

In order to increase the emission efficiency, it is possible to arrange a positive-hole injection layer and/or a positive-hole transportation layer between the anode(s) and the light-emission layers 91R, 91G, and 91B. In addition, in order to increase the emission efficiency, it is also possible to arrange an electron injection layer and/or an electron transportation layer between the cathode(s) and the light-emission layers 91R, 91G, and 91B.

Since the electro-optic device (organic EL device) 5 according to the present embodiment is constructed by using the active-matrix substrate 90 according to the first embodiment explained before, the TFTs 1 constituting the electro-optic device according to the present embodiment are superior in the element uniformity. Therefore, the electro-optic device is greatly superior in the uniformity in the electro-optic characteristics such as the display quality. In addition, since each TFT 1 constituting the organic EL device 4 is superior in the element characteristics, the organic EL device 4 according to the present embodiment is superior to the conventional organic EL devices in reduction in the power consumption and the area on which peripheral circuits are formed, and in high freedom of choice of the types of peripheral circuits.

### 5. VARIATIONS

Although the thin-film devices according to the first and second embodiments are respectively a semiconductor device and a solar cell, the thin-film device according to the present invention is not limited to the above embodiments.

In addition, the non-monocrystalline films to be annealed in the first and second embodiments are crystallized by irradiation with the short-wavelength light, the non-monocrystalline films may be annealed in other manners.

Although each of the inorganic crystalline films 30 and 30-1 is patterned after the inorganic crystalline film is formed on the entire upper surface of the underlying layer in the explained examples, alternatively, each of the inorganic crystalline films 30 and 30-1 may be formed by forming the non-monocrystalline film to be annealed in a pattern, and then crystallizing the patterned non-monocrystalline film. Since the light-cutting layer 20 reduces the proportion of the short-wavelength light L which reaches the substrate 10, even when the non-monocrystalline film to be annealed is patterned, and therefore the non-monocrystalline film to be annealed does not exist over some areas of the upper surface of the substrate 10, it is possible to achieve advantages similar to the explained embodiments.

### 6. INDUSTRIAL USABILITY

The process for producing a thin-film device according to the present invention can be preferably used in manufacture of flexible thin-film devices having a resin substrate such as solar cells, thin-film transistors (TFTs), and the like.

What is claimed is:

1. A process for producing a thin-film device, comprising the steps of:
(A) preparing a substrate which contains a resin material as a main component;
(B) forming a thermal-buffer layer over said substrate;
(C) forming a light-cutting layer over said thermal-buffer layer, where the light-cutting layer prevents damage from short-wavelength light to the substrate by reducing a proportion of the short-wavelength light which reaches the substrate;
(D) forming a non-monocrystalline film over said light-cutting layer, where the non-monocrystalline film transmits said short-wavelength light to such a degree that the short-wavelength light can damage said substrate; and
(E) forming an inorganic film by irradiating said non-monocrystalline film with said short-wavelength light so as to anneal the non-monocrystalline film.

2. A process according to claim 1, wherein said step (D) and said step (E) are performed one or more times after the step (E) is first performed.

3. A process according to claim 1, wherein said inorganic film has crystallinity.

4. A process according to claim 1, wherein said non-monocrystalline film has an energy bandgap of 3.5 eV or greater before the non-monocrystalline film is irradiated with said short-wavelength light.

5. A process according to claim 1, wherein said non-monocrystalline film contains oxide as a main component.

6. A process according to claim 1, wherein the transmittance of said short-wavelength light through said non-monocrystalline film is 10% or higher.

7. A process according to claim 6, wherein the transmittance of said short-wavelength light through said non-monocrystalline film is 30% or higher.

8. A process according to claim 1, wherein said light-cutting layer reduces the proportion of the short-wavelength light which reaches the substrate by absorbing the short-wavelength light.

9. A process according to claim 1, wherein said light-cutting layer reduces the proportion of the short-wavelength light which reaches the substrate by reflecting the short-wavelength light.

10. A process according to claim 1, wherein the transmittance of said short-wavelength light through said light-cutting layer is 10% or less.

11. A process according to claim 10, wherein the transmittance of said short-wavelength light through said light-cutting layer is 5% or less.

12. A process according to claim 1, wherein at least one of said light-cutting layer and said thermal-buffer layer has a function of a gas barrier.

13. A process according to claim 1, wherein said step (A) includes a substep (A-1) of forming a gas-barrier layer on at least one of a bottom surface and an upper surface of said substrate.

14. A process according to claim 1, wherein in said step (D), said non-monocrystalline film is formed by liquid phase deposition.

15. A process according to claim 1, wherein said short-wavelength light is pulsed laser light.

16. A process according to claim 15, wherein said short-wavelength light is excimer laser light.

17. A thin-film device which is produced by said process according to claim 1, and comprises said inorganic film formed in said pattern over said substrate, and the substrate contains said resin material as the main component.

18. A thin-film device according to claim 17, wherein said inorganic film is a semiconductor film.

19. A thin-film device according to claim 17, wherein said inorganic film is a conductive inorganic film.

20. A thin-film device according to claim 18, being a solar cell comprising an active layer realized by said semiconductor film.

21. A thin-film device according to claim 19, being a solar cell comprising at least one of a wire and an electrode which are realized by said conductive inorganic film.

22. A thin-film device according to claim 17, being a solar cell comprising:
at least one of a wire and an electrode which are realized by a conductive inorganic film; and
an active layer realized by a semiconductor film;
wherein each of said conductive inorganic film and said semiconductor film is part of said inorganic film.

23. A thin-film device according to claim 18, being a semiconductor device comprising an active layer realized by said semiconductor film.

24. A thin-film device according to claim 17, being a semiconductor device comprising:
at least one of a wire and an electrode which are realized by a conductive inorganic film; and
an active layer realized by a semiconductor film;
wherein each of said conductive inorganic film and said semiconductor film is part of said inorganic film.

25. An electro-optic device comprising the thin-film device according to claim 23.

26. An electro-optic device comprising the thin-film device according to claim 24.

27. An thin-film sensor comprising the thin-film device according to claim 23.

28. An thin-film sensor comprising the thin-film device according to claim 24.
